(19) United States
(12) Patent Application Publication
(10) Pub. No.: US 2010/0155767 A1
(43) Pub. Date: Jun. 24, 2010

(54) Light emitting device using a micro-rod and method of manufacturing a light emitting device

(75) Inventors: Moon-sang Lee, Seoul (KR); Sung-soo Park, Seongnam-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/461,415

(22) Filed: Aug. 11, 2009

(30) Foreign Application Priority Data
Dec. 23, 2008 (KR) 10-2008-0132512

(51) Int. Cl. H01L 33/00; H01L 21/00

(52) U.S. Cl. 257/99; 438/46; 257/E21.002; 257/E33.062

(57) ABSTRACT

A light emitting device using a micro-rod and a method of manufacturing a light emitting device are provided, the method includes forming a material layer on a substrate. The material layer is patterned such that a hole is formed that exposes a surface of the substrate. A core is grown in the shape of a micro-rod on the surface of the substrate exposed through the hole. A light emitting layer is deposited on the core. A shell is grown on the light emitting layer.

### CROSS-REFERENCE TO RELATED APPLICATIONS

This application claims the benefit of priority under 35 U.S.C. §119 from Korean Patent Application No. 10-2008-0132512, filed on Dec. 23, 2008 in the Korean Intellectual Property Office, the disclosure of which is incorporated herein in its entirety by reference.

### BACKGROUND

1. Field

Example embodiments relate to a light emitting device using a micro-rod. Other example embodiments relate to a method of manufacturing a light emitting device.

2. Description of the Related Art

Research studies have been conducted on nanowires due to their electrical and optical characteristics, and applicability as a light emitting device. In particular, gallium nitride (GaN) nanowires have relatively minor defects that frequently occur in typical light emitting devices (e.g., light emitting diodes (LED) or laser diodes (LD)). For example, defects caused by lattice mismatch between a substrate and GaN are reduced. Research has been conducted in regard to GaN nanowires. A light emitting device manufactured using GaN nanowires may have a relatively large defect density compared to the scale thereof. As such, leakage current is likely to occur, and the operational characteristics of the light emitting device may also be adversely affected. If a light emitting device is manufactured using GaN nanowires, it may be difficult to manufacture the light emitting device due to the nano-size of the GaN nanowires.

### SUMMARY

Example embodiments relate to a light emitting device using a micro-rod. Other example embodiments relate to a method of manufacturing a light emitting device.

Example embodiments include a light emitting device having a core-shell structure using a micro-rod. Other example embodiments relate to a manufacturing method of a light emitting device having a core-shell structure.

The method of manufacturing a light emitting device according to example embodiments includes forming a desired (or select) material layer on a substrate, patterning the material layer to form a hole exposing a surface of the substrate, growing (or forming) a core in the shape of a micro-rod on the surface of the substrate exposed through the hole, depositing a light emitting layer on the core and growing (or forming) a shell on the light emitting layer.

The core and the shell may be grown (or formed) using a hydride vapor phase epitaxy (HVPE) method. The growth (or formation) speed of the core and the shell may be about 50-μm/h to about 200-μm/h.

The light emitting layer may be deposited using a metal organic chemical vapor deposition (MOCVD) method. The deposition speed of the light emitting layer may be about 0.3-μm/h to about 1-μm/h.

The hole formed in the material layer may have a diameter of about 1-μm to about 40-μm.

The light emitting layer may be formed on an outer lateral surface and an upper surface of the core. The shell may be formed on an outer lateral surface and an upper surface of the light emitting layer.

The method may include removing the material layer after growing (or forming) the shell. The method may include forming first and second electrodes to be electrically connected to the core and the shell, respectively.

The core, the light emitting layer and the shell may be formed of a III-V group compound semiconductor. The core may be formed of gallium nitride (GaN). The light emitting layer and the shell may be formed of Al_{y}InₓGa_{1-x-y}N (wherein 0≦y, x≦1, 0≦x+y≦1). The method may include forming an aluminum nitride (AlN) layer on the surface of the substrate exposed through the hole prior to growing the core.

The substrate may be a silicon substrate or a sapphire substrate. The material layer may be formed of a silicon oxide.

Example embodiments may include a light emitting device manufactured according to the above-described method.

The core may have a diameter of about 1-μm to about 40-μm.

The light emitting device may include first and second electrodes electrically connected to the core and the shell, respectively.

An end portion of the core may be formed such that the end portion of the core is exposed to the outside and protrudes from the light emitting layer and the shell.

### BRIEF DESCRIPTION OF THE DRAWINGS

These and/or other aspects will become apparent and more readily appreciated from the following description of example embodiments, taken in conjunction with the accompanying drawings of which:

FIG. 1 is a perspective view illustrating a light emitting device according to example embodiments;

FIG. 2 is a cross-sectional view illustrating the light emitting device shown in FIG. 1;

FIG. 3 illustrates the light emitting device of FIG. 1 connected to a first electrode and a second electrode; and

FIGS. 4 through 8 are cross-sectional views illustrating a method of manufacturing a light emitting device according to example embodiments.

### DETAILED DESCRIPTION

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the invention.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Reference will now be made in detail to embodiments, examples of which are illustrated in the accompanying drawings, wherein like reference numerals refer to like elements throughout, and the sizes and thicknesses of the elements may be exaggerated for clarity of description.

A light emitting device according to example embodiments may be applied to a light emitting diode (LED), a laser diode (LD) and the like. It will also be understood that, if a layer is referred to as being “on” another layer or substrate, it can be directly on the other layer or substrate, or intervening layers may also be present. In this regard, the example embodiments may have different forms and should not be construed as being limited to the descriptions set forth herein. Accordingly, example embodiments are described below, by referring to the drawings, to explain aspects of the present description.

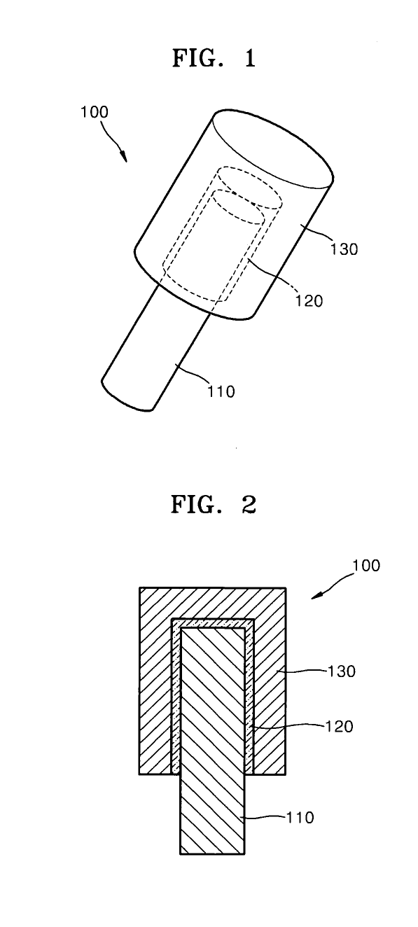

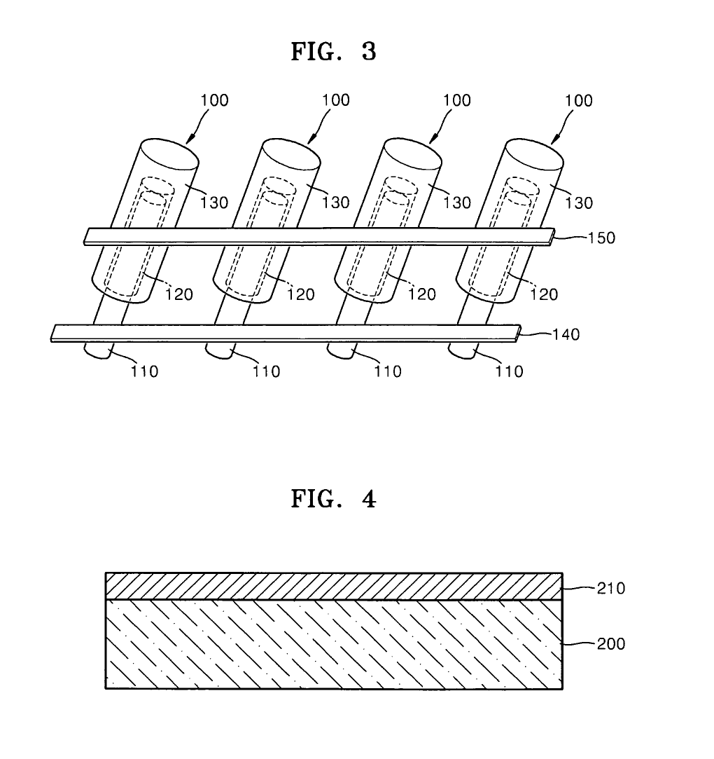

FIG. 1 is a perspective view illustrating a light emitting device according to example embodiments. FIG. 2 is a cross-sectional view of the light emitting device shown FIG. 1.

Referring to FIGS. 1 and 2, a light emitting device 100 has a core-shell structure. The light emitting device 100 includes a core 110 having a shape of a micro-rod, a light emitting layer 120 formed to surround the core 110, and a shell 130 formed to surround the light emitting layer 120. The core 110, the light emitting layer 120 and the shell 130 may be formed of III-V group compound semiconductor(s).

The core 110 may have a diameter of about 1-μm through about 40-μm. The core 110 may have a length of about 1-μm through about 800-μm. An aspect ratio of the core 110 may be about 1 through about 20. However, the core 110 is not limited thereto. The core 110 may be formed such that an end portion of the core 110 is exposed to the outside and protrudes from the light emitting layer 120 and the shell 130. The core 110 may be formed of, for example, GaN. However, the core 110 is not limited thereto. The core 110 may be formed of other various III-V group compound semiconductor(s). The core 110 may be formed in a shape of a micro-rod by performing a hydride vapor phase epitaxy (HVPE) method as will be described later.

The light emitting layer 120 may be formed to surround the core 110. The light emitting layer 120 may partially surround the core 110. The light-emitting layer 120 may surround an end portion of the core 110. The light emitting layer 120 may be formed on an outer lateral surface and an upper surface of the core 110. The light emitting layer 120 may have a multiple quantum well (MQW) structure. The light emitting layer 120 may be formed of, for example, Al_{y}InₓGa_{1-x-y}N (wherein 0≦y, x≦1, 0≦x+y≦1). However, the light emitting layer 120 is not limited thereto. The light emitting layer 120 may be formed of other various III-V group compound semiconductor(s) used as a light emitting material. The light emitting layer 120 may be formed on the core 110 by using (or performing) a metal organic chemical vapor deposition (MOCVD) method as will be described later.

The shell 130 may be formed to surround the light emitting layer 120. The shell 130 may be formed on an outer lateral surface and an upper surface of the light emitting layer 120. The shell 130 may be formed of, for example, Al_{y}InₓGa_{1-x-y}N (wherein 0≦y, x≦1, 0≦x+y≦1). If the core 110 is formed of p-type GaN, the shell 130 may be formed of n-type Al_{y}InₓGa_{1-x-y}N (0≦y, x≦1, 0≦x+y≦1). If the core 110 is formed of n-type GaN, the shell 130 may be formed of p-type Al_{y}InₓGa_{1-x-y}N (0≦y, x≦1, 0≦x+y≦1). However, the shell 130 is not limited thereto. Various other III-V group compound semiconductors may also be used to form the shell 130. The shell 130 may be formed on the light emitting layer 120 using an HVPE method as will be described later.

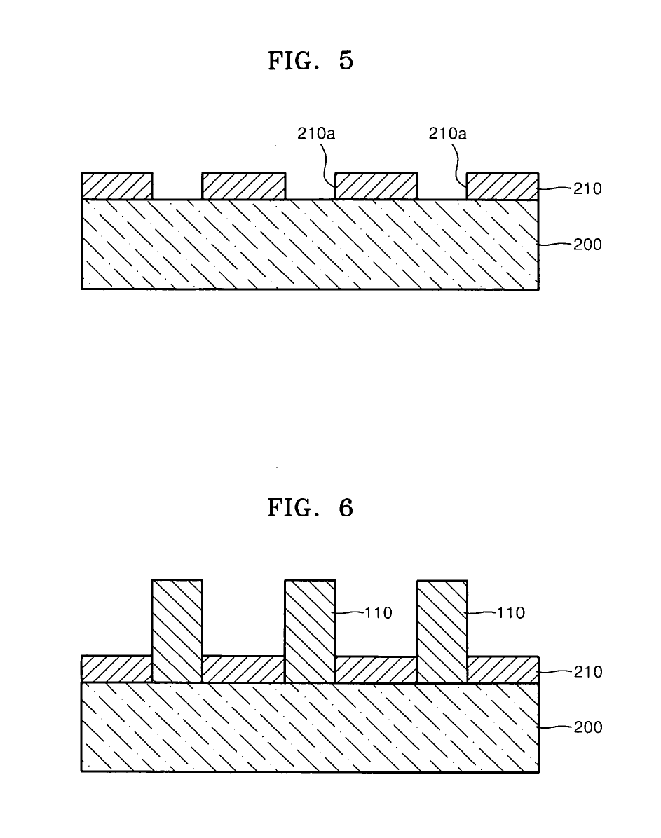

FIG. 3 illustrates the light emitting device of FIG. 1 connected to a first electrode and a second electrode.

Referring to FIG. 3, a first electrode 140 and a second electrode 150 may be connected to a plurality of the light emitting devices 100. The first electrode 140 may be electrically connected to lower end portions of cores 110 that are exposed to the outside. If the cores 110 are formed of a p-type semiconductor material, the first electrode 140 may be a p-type electrode. If the cores 110 are formed of an n-type semiconductor material, the first electrode 140 may be an n-type electrode. The second electrode 150 may be electrically connected to shells 130. If the shells 130 are formed of an n-type semiconductor material, the second electrode 150 may be an n-type electrode. If the shells 130 are formed of a p-type semiconductor material, the second electrode 150 may be a p-type electrode. In the above-described configuration, if a desired voltage is applied to the first and second electrodes 140 and 150, electrons and holes are bonded to each other in light emitting layers 120, thereby emitting light of desired color. The light is emitted outside the light emitting devices 100.

As described above, the light emitting device according to example embodiments have a core-shell structure using a micro-rod. As such, there are less surface defects in the light emitting device according to example embodiments than in light emitting devices using nano-wires. Due to reduced surface defects, the light emitting efficiency of the light emitting device increases.

Hereinafter, a method of manufacturing a light emitting device will be described.

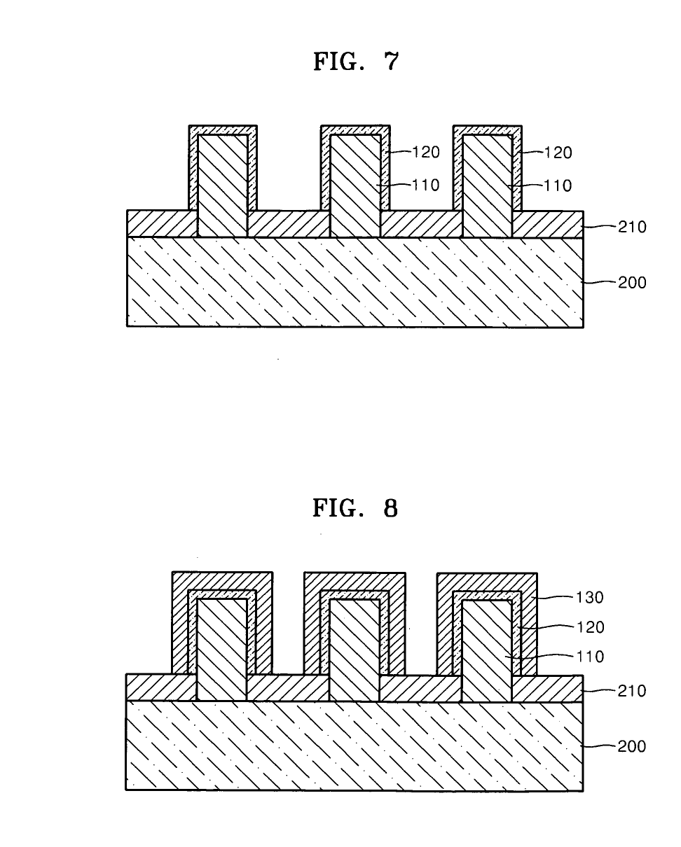

FIGS. 4 through 8 are cross-sectional views illustrating a method of manufacturing a light emitting device according to example embodiments.

Referring to FIG. 4, a substrate 200 is prepared. The substrate 200 may be formed of a silicon substrate or a sapphire substrate. However, the substrate 200 is not limited thereto.

A desired (or select) material layer 210 is formed on the substrate 200. The material layer 210 may be formed of a silicon oxide, but is not limited thereto. For example, the material layer 210 may be formed by depositing a silicon oxide on the substrate 200 by using (or performing) a chemical vapor deposition (CVD) method, a sputtering method, an evaporation method or the like. The material layer 210 may be formed to have a thickness of about 10-μm to about 100-μm, but is not limited thereto.

Referring to FIG. 5, a plurality of holes 210a exposing an upper surface of the substrate 200 are formed by patterning the material layer 210 by using (or performing) a photolithography process. The holes 210 may have a diameter of about 1-μm to about 40-μm, but are not limited thereto.

Referring to FIG. 6, cores 110 are formed on portions of the upper surface of the surface exposed through (or by) the holes 210a. The cores 110 may be formed by growing a III-V group compound semiconductor (e.g., GaN) in the shape of a micro-rod. The cores 110 may be grown (or formed) using a hydride vapor phase epitaxy (HVPE) method. The growth (or formation) speed of the cores 110 may be about 5-μm/h to about 200-μm/h. A temperature of the growth process of the cores 110 may be about 900° C. to about 1100° C. A III/V group compound semiconductor ratio may be about 10 to about 2000, but example embodiments are not limited thereto. The cores 110 grown using the HVPE method may have a diameter of about 1-μm to about 40-μm to correspond to the diameter of the holes 120a. The length of the grown cores 110 may be about 1-μm to about 800-μm, and an aspect ratio of the cores 110 may be about 1 to about 20. However, the cores 110 are not limited thereto.

An aluminum nitride (AlN) layer (not shown) for growing GaN on the upper surface of the substrate 200 exposed through the holes 210a may be formed before the cores 110 undergo the growth process.

Referring to FIG. 7, light emitting layers 120 are deposited on the cores 110. The light emitting layers 120 may be formed by depositing a III-V group compound semiconductor (e.g., Al_{y}InₓGa_{1-x-y}N (wherein 0≦y, x≦1, 0≦x+y≦1)) on an outer lateral surface and an upper surface of the cores 110. As described above, the light emitting layers 120 may be deposited on the cores 110 three-dimensionally in vertical and/or horizontal directions. The deposition speed of the light emitting layers 120 may be about 0.3-μm/h to about 1-μm/h. The process temperature in the deposition process of the light emitting layers 120 may be about 900° C. to about 1100° C. A III/V group compound semiconductor ratio may be about 10 to about 2000. However, example embodiment are not limited thereto.

Referring to FIG. 8, shells 130 are grown (or formed) on the light emitting layers 120. The shells 130 may be formed by growing a III-V compound semiconductor (e.g., Al_{y}InₓGa_{1-x-y}N (wherein 0≦y, x≦1, 0≦x+y≦1)) on an outer lateral surface and an upper surface of the light emitting layers 120 by using an HVPE method. The growth speed of the shells 130 may be about 5-μm/h to about 200-μm/h. The process temperature of the growth process of the shells 130 may be about 900° C. to about 1100° C. A III/V group compound semiconductor ratio may be about 10 to about 2000. However, example embodiments are not limited thereto.

The material layer 210 may be removed using, for example, an hafnium (Hf) solution, exposing lower end portions of the cores 110. The first electrode 140 (see FIG. 3) may be connected to the lower end portions of the cores 110. The second electrode 150 (see FIG. 3) may be connected to the shells 130. If the cores 110 have small exposed portions, the shells 130 and the light emitting layers 120 may be sequentially dry-etched using a focused ion beam (FIB) to expose the cores 110. The first electrode 140 may be connected to exposed portions of the cores 110.

As described above, according to example embodiments, a light emitting device having a core-shell structure is manufactured using a micro-rod having a larger diameter than nanowires, thereby increasing a light emitting surface and light emitting efficiency and reducing surface defect density.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of various example embodiments and is not to be construed as limited to the specific embodiments disclosed, and that modifications to the disclosed embodiments, as well as other embodiments, are intended to be included within the scope of the appended claims.

What is claimed is:

1. A method of manufacturing a light emitting device, the method comprising:
forming a material layer on a substrate;
patterning the material layer such that a hole is formed that exposes a surface of the substrate;
forming a core in the shape of a micro-rod on the surface of the substrate exposed through the hole;
depositing a light emitting layer on the core; and
forming a shell on the light emitting layer.

2. The method of claim 1, wherein forming the core and the shell include performing a hydride vapor phase epitaxy (HVPE) method.

3. The method of claim 2, wherein the core and the shell are formed at a speed of about 50-μm/h to about 200-μm/h.

4. The method of claim 2, wherein depositing the light emitting layer includes performing a metal organic chemical vapor deposition (MOCVD) method.

5. The method of claim 4, wherein the light emitting layer is deposited at a speed of about 0.3-μm/h to about 1-μm/h.

6. The method of claim 1, wherein the hole formed in the material layer has a diameter of about 1-μm to about 40-μm.

7. The method of claim 1, wherein the light emitting layer is formed on an outer lateral surface and an upper surface of the core.

8. The method of claim 7, wherein the shell is formed on an outer lateral surface and an upper surface of the light emitting layer.

9. The method of claim 1, further comprising removing the material layer after forming the shell.

10. The method of claim 1, further comprising forming a first electrode and a second electrode electrically connected to the core and the shell, respectively.

11. The method of claim 1, wherein the core, the light emitting layer, and the shell are formed of a III-V group compound semiconductor.

12. The method of claim 11, wherein the core is formed of gallium nitride (GaN).

13. The method of claim 12, wherein the light emitting layer and the shell are formed of Al_{y}InₓGa_{1-x-y}N (wherein 0≦y, x≦1, 0≦x+y≦1).

14. The method of claim 1, wherein the substrate is a silicon substrate or a sapphire substrate.

15. The method of claim 15, wherein the material layer is formed of a silicon oxide.

16. A light emitting device manufactured according to the method of claim 1.

17. The light emitting device of claim 17, wherein the core has a diameter of about 1-μm to about 40-μm.

18. The light emitting device of claim 17, further comprising a first electrode and a second electrode electrically connected to the core and the shell, respectively.

19. The light emitting device of claim 17, wherein an end portion of the core is exposed to the outside and protrudes from the light emitting layer and the shell.
